(19) United States
(12) Patent Application Publication
(10) Pub. No.: US 2025/0006654 A1
(43) Pub. Date: Jan. 2, 2025

(54) SEMICONDUCTOR DEVICE HAVING TEST PATTERN

(71) Applicant: Samsung Electronics Co., Ltd., Suwon-si (KR)

(72) Inventors: Seunghye BAEK, Suwon-si (KR); Jeonghyun KIM, Suwon-si (KR); Hyunjae KANG, Suwon-si (KR); Ilhwan KIM, Suwon-si (KR); Jongsu KIM, Suwon-si (KR); Youngsik PARK, Suwon-si (KR); Muyoung LEE, Suwon-si (KR); Sangho JO, Suwon-si (KR)

(73) Assignee: Samsung Electronics Co., Ltd., Suwon-si (KR)

(21) Appl. No.: 18/630,178

(22) Filed: Apr. 9, 2024

(30) Foreign Application Priority Data
Jun. 29, 2023 (KR) 10-2023-0084528

(51) Int. Cl. H01L 23/544

(52) U.S. Cl. CPC H01L 23/544; H01L 2223/5446

(57) ABSTRACT

A semiconductor device includes a semiconductor substrate, a first test pattern disposed on the semiconductor substrate, and a second test pattern located adjacent to the first test pattern. The first test pattern includes an overlay pattern, and the second test pattern includes a test element group.

### CROSS-REFERENCE TO RELATED APPLICATION

This application is based on and claims priority under 35 U.S.C. § 119 to Korean Patent Application No. 10-2023-0084528, filed on Jun. 29, 2023, in the Korean Intellectual Property Office, the disclosure of which is incorporated by reference herein in its entirety.

### BACKGROUND

Various inventive concepts relate to a semiconductor device including a test pattern, and a semiconductor device including an overlay pattern and/or a test element group.

Various methods are used to align the overlay between layers of different vertical levels within a margin of error. For example, an optical method and a method using a scanning electron microscope are also used. However, as the sizes of patterns to be manufactured on a substrate become smaller, overlay consistency deteriorates. Accordingly, there is a need for semiconductor devices having excellent or improved overlay consistency even though the size of patterns is reduced.

### SUMMARY

Various inventive concepts provide a semiconductor device having improved and/or increased space efficiency.

Also, it is understood that the present inventive concepts are not limited to the aforementioned, and various changes and modifications not described herein can be made and be clearly understood by those skilled in the art from the following description.

In some example embodiments, there is provided a semiconductor device including a semiconductor substrate, a first test pattern on the semiconductor substrate, and a second test pattern adjacent to the first test pattern, wherein the first test pattern includes an overlay pattern, and the second test pattern includes a test element group.

In some example embodiments, there is provided a semiconductor device including a semiconductor substrate that includes an in-cell region and a scribe lane defining the in-cell region, a first test pattern on the semiconductor substrate, and a second test pattern adjacent to the first test pattern, wherein the first test pattern includes a first overlay pattern, the first test pattern includes a plurality of lower marks and a plurality of upper marks that are at different vertical levels, at least one of the plurality of lower marks and at least one of the plurality of upper marks overlap each other in a vertical direction, and a pitch of each of the plurality of lower marks is different from a pitch of each of the plurality of upper marks.

In some example embodiments, there is provided a semiconductor device including a semiconductor substrate that includes an in-cell region and a scribe lane defining the in-cell region, a first overlay pattern on the semiconductor substrate, and a second overlay pattern surrounded by the first overlay pattern, wherein the first overlay pattern includes a plurality of lower marks and a plurality of upper marks that are at different vertical levels, at least one of the plurality of lower marks and at least one of the plurality of upper marks overlap each other in a vertical direction, a pitch of each of the plurality of lower marks is different from a pitch of each of the plurality of upper marks, the first overlay pattern includes an after development inspection (ADI) overlay pattern, and the second overlay pattern includes an after cleaning inspection (ACI) overlay pattern.

### BRIEF DESCRIPTION OF THE DRAWINGS

Various example embodiments will be more clearly understood from the following detailed description taken in conjunction with the accompanying drawings in which:

FIG. 1 is a plan view showing a semiconductor substrate for forming a semiconductor device according to an example embodiment;

FIG. 2 is a partially enlarged view of some semiconductor dies of FIG. 1;

FIG. 3 is a plan view showing a test pattern group according to an example embodiment;

FIG. 4 is a cross-sectional view showing a test pattern group according to an example embodiment;

FIG. 5 is a plan view showing a test pattern group according to an example embodiment;

FIG. 6 is a plan view showing a test pattern group according to an example embodiment;

FIG. 7 is a plan view showing a test pattern group according to an example embodiment;

FIG. 8 is a plan view showing a test pattern group according to an example embodiment;

FIG. 9 is a block diagram showing a process system for manufacturing a semiconductor device according to an example embodiment;

FIG. 10 is a block diagram for explaining first and second measurement devices and a control device of FIG. 9;

FIG. 11 is a flowchart showing a method of testing a semiconductor device using test groups, according to an example embodiment; and

FIG. 12 is a partially enlarged view of some semiconductor dies of FIG. 1.

### DETAILED DESCRIPTION

Hereinafter, various example embodiments are described with reference to the accompanying drawings. The same reference numerals are given to the same elements in the drawings, and repeated descriptions thereof are omitted.

As described herein, an element that is “on” another element may be above or beneath or adjacent (e.g., horizontally adjacent) to the other element. An element that is on another clement may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

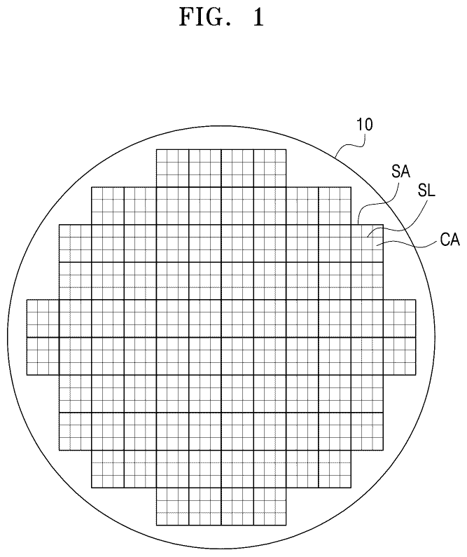

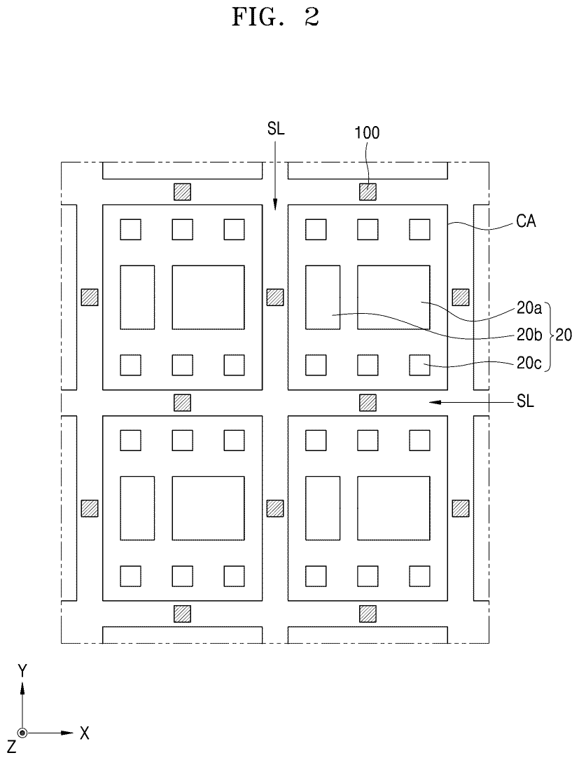

FIG. 1 is a plan view showing a semiconductor substrate 10 for forming a semiconductor device according to an example embodiment. FIG. 2 is a partially enlarged view of some semiconductor dies of FIG. 1.

Referring to FIGS. 1 and 2, the semiconductor substrate 10 may have a plurality of shot regions SA. Each of the shot regions SA may refer to a region that is exposed through a single exposure process. One shot region SA may include one chip region CA or a plurality of chip regions CA. A scribe lane region SL may be located between the chip regions CA. The chip regions CA may be defined by the scribe lane region SL.

Each of the chip regions CA may include a plurality of circuit regions 20. Each of the plurality of circuit regions 20 may include a logic circuit region 20a, a memory region 20b, an input/output element region 20c, and the like. Here, the chip region CA may be referred to as an ‘in-cell region’.

In some example embodiments, a plurality of test pattern groups 100 may be substantially evenly arranged on the semiconductor substrate 10. In some example embodiments, the plurality of test pattern groups 100 may be evenly arranged on the scribe lane region SL. In some example embodiments, the plurality of test pattern groups 100 may be evenly arranged on the chip region CA (the in-cell region). In some example embodiments, the plurality of test pattern groups 100 may be evenly arranged on the semiconductor substrate 10 regardless of the scribe lane region SL and the chip region CA.

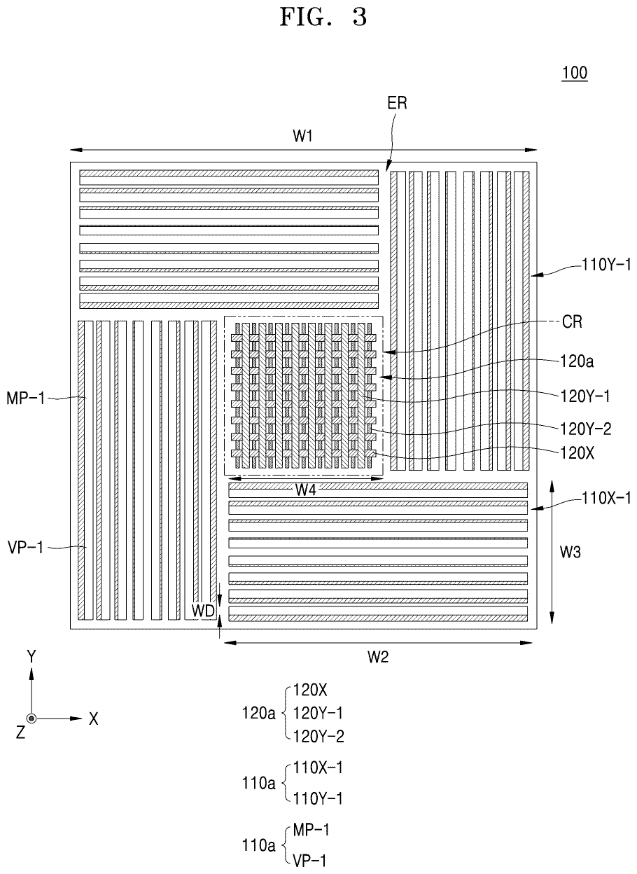

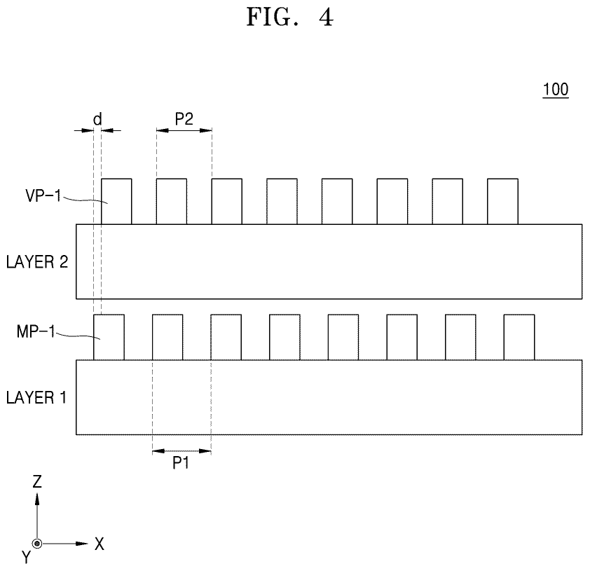

FIG. 3 is a plan view showing a test pattern group 100 according to an example embodiment, and FIG. 4 is a cross-sectional view showing the test pattern group 100 according to an example embodiment.

Referring to FIGS. 3 and 4, the test pattern group 100 may include a first test pattern 110a and a second test pattern 120a. The first test pattern 110a may also be referred to as a first overlay pattern 110a. The second test pattern 120a may also be referred to as a second overlay pattern 120a.

The test pattern group 100 may include the first overlay pattern 110a and the second overlay pattern 120a. In a plan view, the test pattern group 100 may include a central region CR and an edge region ER surrounding the central region CR. The central region CR and the edge region ER may be adjacent to each other. The horizontal area of the central region CR may be less than the horizontal area of the edge region ER. The first overlay pattern 110a may be disposed on the edge region ER, and the second overlay pattern 120a may be disposed on the central region CR. A first width W1, which is the horizontal width of the test pattern group 100, may be in a range from about 9 micrometers to about 60 micrometers. FIG. 3 illustrates that the test pattern group 100 has a square shape, but the shape of the test pattern group 100 may be variously modified. For example, the test pattern group 100 may have a rectangular shape, a circular shape, a rhombic shape, a polygonal shape, and/or an atypical shape, but example embodiments are not limited thereto.

The edge region ER may be divided into four quadrants having a quadrangular shape (e.g., a rectangular or a square shape). The first overlay pattern 110a may be located in each of the quadrants. The first overlay pattern 110a may include a plurality of grating-shaped patterns, a plurality of bar-shaped patterns, and/or a plurality of slit-shaped patterns, but example embodiments are not limited thereto. For example, the first overlay pattern 110a may include a line-and-space pattern. The first overlay pattern 110a may have a pinwheel shape, and line-and-space patterns of the first overlay pattern 110a in each of the four quadrants may be arranged perpendicularly and parallel to each other.

The first overlay pattern 110a may include a plurality of first overlay marks 110X-1 that include a plurality of line-and-space patterns extending in a first horizontal direction (X direction). Also, the first overlay pattern 110a may include a plurality of second overlay marks 110Y-1 that include a plurality of line-and-space patterns extending in a second horizontal direction (Y direction). Each of the first and second overlay marks 110X-1 and 110Y-1 may have a horizontal length in a direction in which each of the first and second overlay marks 110X-1 and 110Y-1 extends. Each of the first and second overlay marks 110X-1 and 110Y-1 may have a horizontal width in a horizontal direction (X direction and/or Y direction) perpendicular to the direction in which each of the first and second overlay marks 110X-1 and 110Y-1 extends. The first overlay mark 110X-1 may have the horizontal length in the first horizontal direction (X direction) and the horizontal width in the second horizontal direction (Y direction). In the same manner, the second overlay mark 110Y-1 may have the horizontal width in the first horizontal direction (X direction) and the horizontal length in the second horizontal direction (Y direction). A second width W2, which is the length of each of the first and second overlay marks 110X-1 and 110Y-1, may be in a range from about 5 micrometers to about 40 micrometers. For example, the second width W2, which is the length of the long side of each of the four quadrants, may be in a range from about 5 micrometers to about 40 micrometers, and a third width W3, which is the length of the short side of each of the four quadrants, may be in a range from about 3 micrometers to about 20 micrometers. Also, a horizontal width WD of each of the first and second overlay marks 110X-1 and 110Y-1 may be in a range from about 100 nanometers to about 500 nanometers.

As used herein, a direction parallel to a main surface of the semiconductor substrate 10 may be referred to as a horizontal direction (X direction and/or Y direction), and a direction perpendicular to the horizontal direction (X direction and/or Y direction) may be referred to as a vertical direction (Z direction).

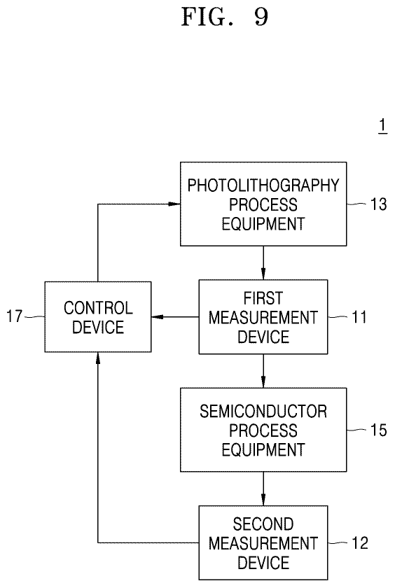

The first overlay pattern 110a may be used to measure an overlay using a first measurement device 11 (FIG. 9) which is described below. For example, a photoresist pattern is formed on the first overlay pattern 110a by performing a photolithography process on the first overlay pattern 110a. Also, before performing a subsequent process (e.g., an etching process) using the photoresist pattern, overlay measurement may be performed using the photoresist pattern. For example, the first overlay pattern 110a may include an overlay pattern measured during an after development inspection (ADI).

The first overlay pattern 110a may include an image based overlay (IBO) mark. The IBO mark may include a main pattern MP-1 formed on a lower layer (LAYER 1) and a vernier pattern VP-1 formed on a current layer (LAYER 2). For example, in the first overlay pattern 110a, dark patterns may be formed on the lower layer (LAYER 1) as the main pattern MP-1, and bright patterns may be formed on the current layer (LAYER 2) as the vernier pattern VP-1. The horizontal width of the main pattern MP-1 may be the same as that of the vernier pattern VP-1. In another example embodiment, the horizontal width of the main pattern MP-1 may be different from that of the vernier pattern VP-1.

The first measurement device 11 (FIG. 9) may measure the overlay by performing signal processing on an optic/camera image of the IBO mark. For example, the first measurement device 11 (FIG. 9) may perform the signal processing on the images of the main pattern MP-1 and the vernier pattern VP-1 to calculate relative positions between the main pattern MP-1 and the vernier pattern VP-1, thereby measuring the overlay.

The first overlay pattern 110a may include, for example, a Moiré pattern. The Moiré pattern may include an interference pattern generated when a plurality of different regular patterns overlap each other. In order to form the Moiré pattern, a first pitch P1, which is the pitch of the main pattern MP-1, and a second pitch P2, which is the pitch of the vernier pattern VP-1, may be different from each other. Each of the first and second pitches P1 and P2 may be in a range from about 300 nanometers to about 900 nanometers. In another example embodiment, each of the first and second pitches P1 and P2 may have the same range as wavelengths of ultra violet (UV) and/or near-infrared (NIR) light. Since the first and second pitches P1 and P2 are different from each other, the main pattern MP-1 and the vernier pattern VP-1 may be arranged with an overlay offset d. At least one of a plurality of main patterns MP-1 may at least partially overlap at least one of a plurality of vernier patterns VP-1 in the vertical direction (Z direction).

The second overlay pattern 120a may be used to measure an overlay using a second measurement device 12 (FIG. 9) which is described below. The second overlay pattern 120a may include a conductive pattern. For example, an etching process and a cleaning process may be performed on a substrate to form a metal pattern, and the overlay measurement may be performed using the conductive pattern.

For example, the second overlay pattern 120a may include an overlay pattern measured during an after cleaning inspection (ACI). The ACI may actually refer to an inspection after an etching process for forming a pattern on a substrate.

The size of the second overlay pattern 120a shown in FIG. 3 may be enlarged for clarity. In some example embodiments, the second overlay pattern 120a may have a smaller planar area than the first overlay pattern 110a. A fourth width W4, which is the horizontal width of the second overlay pattern 120a, may be in a range from about 3 micrometers to about 20 micrometers. For example, each of the plurality of first to third additional overlay marks 120X, 120Y-1, and 120Y-2 of the second overlay pattern 120a may have a length of about 3 micrometers to about 20 micrometers.

The second overlay pattern 120a may include the first additional overlay mark 120X extending in the first horizontal direction (X direction) and the second and third additional overlay marks 120Y-1 and 120Y-2 extending in the second horizontal direction (Y direction). In a plan view, each of the first to third additional overlay marks 120X, 120Y-1, and 120Y-2 may have a grating, a bar, and/or a slit shape, but example embodiments are not limited thereto. The second and third additional overlay marks 120Y-1 and 120Y-2 may be spaced apart from each other in the first horizontal direction (X direction). The first and second additional overlay marks 120X and 120Y-1 may overlap each other in the vertical direction (Z direction), and the first and third additional overlay marks 120X and 120Y-2 may overlap each other in the vertical direction (Z direction). The shape of the second overlay pattern 120a is not limited thereto and may be variously modified. Each of the plurality of first and second overlay marks 110X-1 and 110Y-1 of the first overlay pattern 110a may have a length greater than that of each of plurality of first to third additional overlay marks 120X, 120Y-1, and 120Y-2 of the second overlay pattern 120a.

Each of first to third additional overlay marks 120X, 120Y-1, and 120Y-2 may have a corresponding cell pattern in the chip region CA. In some example embodiments, each of the first to third additional overlay marks 120X, 120Y-1, and 120Y-2 may be formed simultaneously with a specific cell pattern located in the chip region CA at the same vertical level as each of the first to third additional overlay marks 120X, 120Y-1, and 120Y-2. In another example embodiment, each of the first to third additional overlay marks 120X, 120Y-1, and 120Y-2 may be formed at a different time point from a specific cell pattern located in the chip region CA at the same vertical level as each of the first to third additional overlay marks 120X, 120Y-1, and 120Y-2.

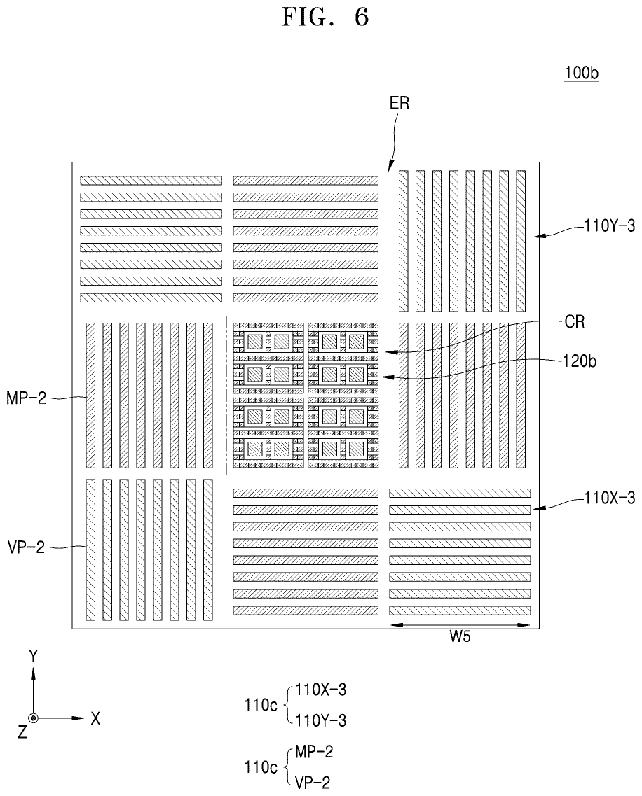

FIG. 3 illustrates, as an example, that the second overlay pattern 120a is located in the central region CR, but a test element group 120b of FIGS. 6 to 8 may be located in the central region CR.

In a general test pattern group, a first overlay pattern and a second overlay pattern are spaced apart from each other. Since the first and second overlay patterns are spaced apart from each other, a measurement error may increase according to the arrangement positions of patterns. Also, in the general test pattern group, a space for arranging the first overlay pattern and a space for arranging the second overlay pattern are required or advantageous, and thus, relatively large spaces are required or preferable in a semiconductor substrate.

On the other hand, in the test pattern group 100 according to the inventive concepts, the first overlay pattern 110a and the second overlay pattern 120a are arranged adjacent to each other. Therefore, it is possible to measure a first overlay and a second overlay without occupying a relatively large space in the semiconductor substrate 10. Also, since the first overlay pattern 110a and the second overlay pattern 120a are adjacent to each other, it is possible to reduce or prevent a measurement error of the first overlay and a measurement error of the second overlay.

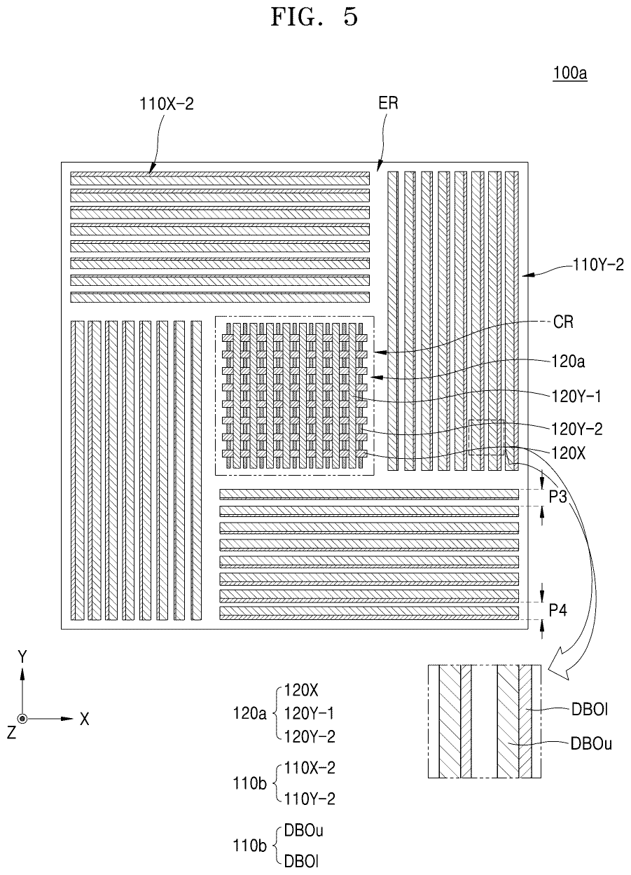

FIG. 5 is a plan view showing a test pattern group 100a according to an example embodiment. A description is given below with reference to FIGS. 1 to 4 together.

Referring to FIG. 5, the test pattern group 100a may include a first overlay pattern 110b and the second overlay pattern 120a. The first overlay pattern 110b may include a third overlay mark 110X-2 extending in the first horizontal direction (X direction) and a fourth overlay mark 110Y-2 extending in the second horizontal direction (Y direction).

The first overlay pattern 110b may include a diffraction based overlay (DBO) mark. The DBO mark may include a lower pattern DBOl and an upper pattern DBOu. The first measurement device 11 (FIG. 9) may detect light incident on and diffracted from the DBO mark and may perform signal processing on the diffracted light to measure an overlay. For example, the first measurement device 11 (FIG. 9) may detect signals reflected and diffracted from the DBO mark, compare the intensities of primary components of the diffracted signals, and measure the overlay.

The first overlay pattern 110b may also include a Moiré pattern. Therefore, a third pitch P3, which is the pitch of the upper pattern DBOu, and a fourth pitch P4, which is the pitch of the lower pattern DBOl, may be different from each other. At least one of a plurality of upper patterns DBOu may overlap at least one of a plurality of lower patterns DBOl in the vertical direction (Z direction).

FIG. 5 illustrates, as an example, that the second overlay pattern 120a is located in the central region CR, but a test element group 120b of FIGS. 6 to 8 may be located in the central region CR.

FIG. 6 is a plan view showing a test pattern group 100b according to an example embodiment. A description is given below with reference to FIGS. 1 to 5 together.

Referring to FIG. 6, the test pattern group 100b may include a first overlay pattern 110c and a test element group (TEG) 120b. In a plan view, the first overlay pattern 110c may be located in an edge region ER of the test pattern group 100b, and the TEG 120b may be located in a central region CR of the test pattern group 100b.

The first overlay pattern 110c may include an IBO mark. The IBO mark may include a main pattern MP-2 formed on a lower layer (LAYER 1) and a vernier pattern VP-2 formed on a current layer (LAYER 2).

FIG. 6 illustrates, as an example, a case in which the first overlay pattern 110c includes an advanced image metrology (AIM) overlay mark, but inventive concepts are not limited thereto. For example, the first overlay pattern 110c may include a box in box (BIB) overlay mark. In another example embodiment, the first overlay pattern 110c may include a Moiré pattern.

The first overlay pattern 110c may include a plurality of fifth overlay marks 110X-3 that include a plurality of line-and-space patterns extending in the first horizontal direction (X direction). Also, the first overlay pattern 110c may include a plurality of sixth overlay marks 110Y-3 that include a plurality of line-and-space patterns extending in the second horizontal direction (Y direction). Each of the fifth and sixth overlay marks 110X-3 and 110Y-3 may have a horizontal length in a direction in which each of the fifth and sixth overlay marks 110X-3 and 110Y-3 extends. Each of the fifth and sixth overlay marks 110X-3 and 110Y-3 may have a horizontal width in a horizontal direction (X direction and/or Y direction) perpendicular to the direction in which each of the fifth and sixth overlay marks 110X-3 and 110Y-3 extends. The fifth overlay mark 110X-3 may have the horizontal length in the first horizontal direction (X direction) and the horizontal width in the second horizontal direction (Y direction). In the same manner, the sixth overlay marks 110Y-3 may have the horizontal width in the first horizontal direction (X direction) and the horizontal length in the second horizontal direction (Y direction). A fifth width W5 may be in a range from about 3 micrometers to about 20 micrometers.

In the four quadrants, a plurality of main patterns MP-2 and a plurality of vernier patterns VP-2 may be respectively spaced apart from each other in the horizontal direction (X direction and/or Y direction) parallel to the direction in which each of the main patterns MP-2 and each of the vernier patterns VP-2 extend.

In a plan view, the main patterns MP-2 may not overlap the vernier patterns VP-2 in a vertical direction (Z direction). For example, the main patterns MP-2 and the vernier patterns VP-2 may be spaced apart from each other in the horizontal direction (X direction and/or Y direction).

The TEG 120b may include a mark for measuring a critical dimension (CD) of a pattern of the semiconductor substrate 10. For example, the TEG 120b may include a mark for measuring the thickness and/or line width of the pattern of the semiconductor substrate 10.

The TEG 120b may include a plurality of marks for testing a manufacturing process of a semiconductor device and characteristics of the completed semiconductor device. FIG. 6 illustrates, as an example, that the TEG 120b includes a rectangular mark and another rectangular mark surrounding the rectangular mark, but the shape and arrangement of the marks of the TEG 120b may be variously modified.

The TEG 120b may have a smaller planar area than the first overlay pattern 110c. For example, each of the plurality of marks of the TEG 120b may have a smaller planar area than each of the plurality of overlay marks of each of the first overlay pattern 110c.

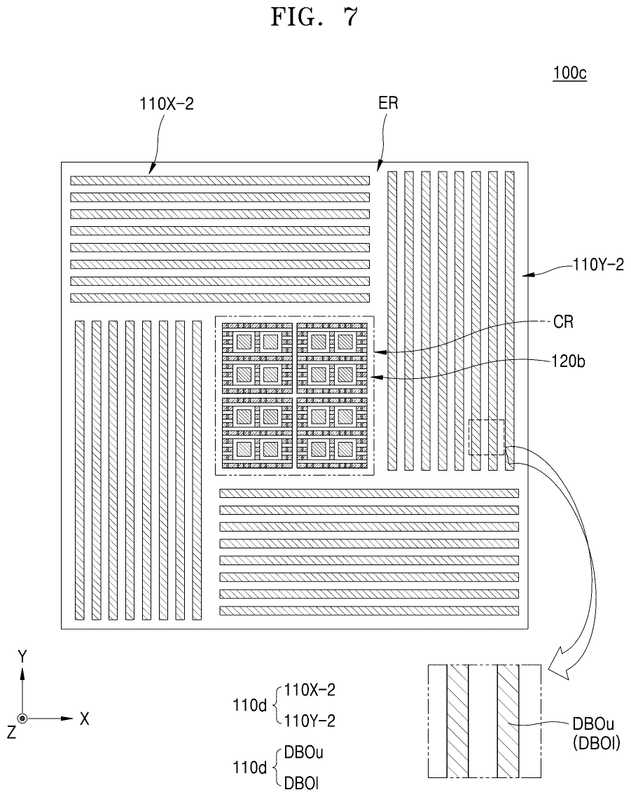

FIG. 7 is a plan view showing a test pattern group 100c according to an example embodiment. A description is given below with reference to FIGS. 1 to 6 together.

Referring to FIG. 7, the test pattern group 100c may include a first overlay pattern 110d and a TEG 120b. The TEG 120b of FIG. 7 is substantially the same as the TEG 120b of FIG. 6, and thus, the first overlay pattern 110d is mainly described below.

The first overlay pattern 110d may include a DBO mark. The DBO mark may include a lower pattern DBOl and an upper pattern DBOu. The first measurement device 11 (FIG. 9) may detect light incident on and diffracted from the DBO mark and may perform signal processing on the diffracted light to measure an overlay. For example, the first measurement device 11 (FIG. 9) may detect signals reflected and diffracted from the DBO mark, compare the intensities of primary components of the diffracted signals, and measure the overlay.

The first overlay pattern 110d may include a plurality of upper patterns DBOu and a plurality of lower patterns DBOl. In a plan view, the plurality of upper patterns DBOu may respectively overlap the plurality of lower patterns DBOl in a vertical direction (Z direction). Each of the plurality of upper patterns DBOu may have the same pitch as each of the plurality of lower patterns DBOl.

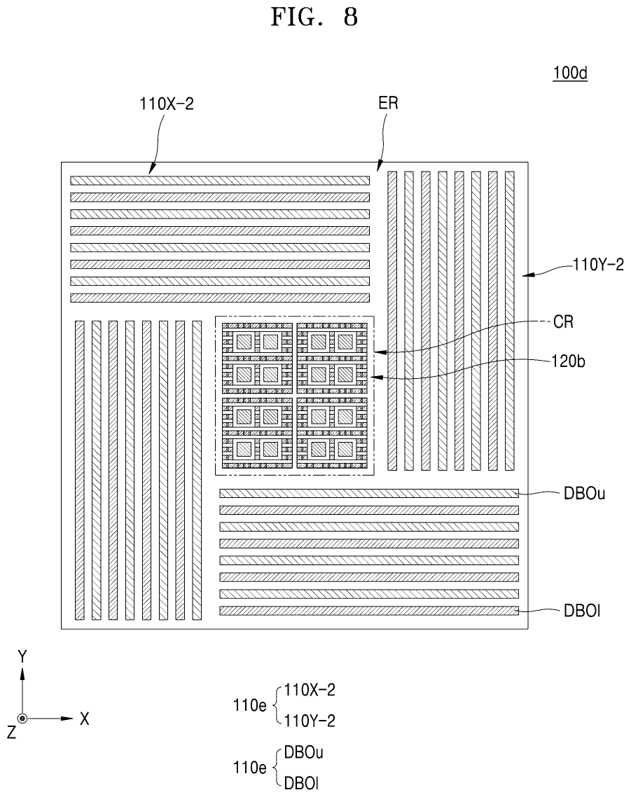

FIG. 8 is a plan view showing a test pattern group 100d according to an example embodiment. A description is given below with reference to FIGS. 1 to 7 together.

Referring to FIG. 8, the test pattern group 100d may include a first overlay pattern 110c and a TEG 120b. The TEG 120b of FIG. 8 is substantially the same as the TEG 120b of FIG. 6, and thus, the first overlay pattern 110e is mainly described below.

The first overlay pattern 110e may include a plurality of upper patterns DBOu and a plurality of lower patterns DBOl. In a plan view, the plurality of upper patterns DBOu may not overlap the plurality of lower patterns DBOl in a vertical direction (Z direction). For example, the plurality of upper patterns DBOu may be respectively spaced apart from of the plurality of lower patterns DBOl in a horizontal direction (X direction and/or Y direction). In the four quadrants, the plurality of upper patterns DBOu and the plurality of lower patterns DBOl may be respectively spaced apart from each other in the horizontal direction (X direction and/or Y direction) perpendicular to the direction in which each of the plurality of upper patterns DBOu and each of the plurality of lower patterns DBOl extend. Each of the plurality of upper patterns DBOu may have the same pitch as each of the plurality of lower patterns DBOl.

FIG. 9 is a block diagram showing a process system for manufacturing a semiconductor device according to an example embodiment. A description is given below with reference to FIGS. 1 to 8 together.

Referring to FIG. 9, a semiconductor process system 1 may include photolithography process equipment 13 for performing a photolithography process, a first measurement device 11 for performing first overlay measurement using a photoresist pattern formed using the photolithography process equipment 13, semiconductor process equipment 15 for performing subsequent processes using the photoresist pattern, and a second measurement device 12 for performing second overlay measurement using a second test pattern formed by using the semiconductor process equipment 15. The second test pattern may include the second overlay pattern 120a and/or the TEG 120b. Also, the second measurement may include second overlay measurement and/or CD measurement of the pattern of the semiconductor substrate 10 using the TEG 120b. In addition, the semiconductor process system 1 may include a control device 17 capable of transmitting signals to and receiving signals from the first and second measurement devices 11 and 12.

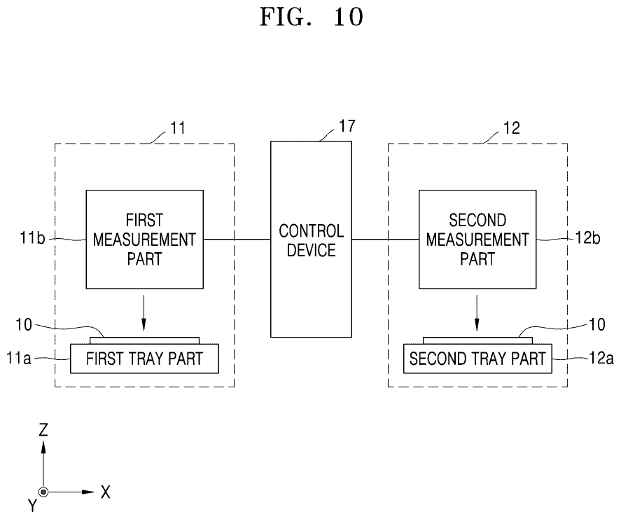

The first and second measurement devices 11 and 12 and the control device 17 are described with reference to FIG. 10. FIG. 10 is a block diagram for explaining the first and second measurement devices 11 and 12 and the control device 17 of FIG. 9.

Referring to FIGS. 9 and 10, the first measurement device 11 may include a first tray part 11a, on which the semiconductor substrate 10 having the photoresist pattern (the first test pattern) formed by the photolithography process equipment 13 is placed, and a first measurement part 11b, which performs measurement using the photoresist pattern. The first measurement part 11b may measure test target patterns using diffraction of light (e.g., the first overlay measurement), and the control device 17 may generate first error data using measurement data obtained from the first measurement part 11b. The first error data generated as described above may be fed back to the photolithography process equipment 13.

The second measurement device 12 may include a second tray part 12a, on which the semiconductor substrate 10 having the second test pattern formed by the semiconductor process equipment 15 is placed, and a second measurement part 12b, which performs measurement using the second test pattern.

In some example embodiments, when the second test pattern includes the second overlay pattern 120a, the second measurement device 12 may include a measurement device using a scanning electron microscope (SEM). For example, the second measurement device 12 may emit an electron beam having a landing energy of about 10 keV or more so as to extract SEM images of metallic patterns stacked in at least two or three layers. The control device 17 may generate overlay error data using the SEM image extracted from the second measurement device 12. The overlay error data generated as described above may be fed back to the photolithography process equipment 13.

Also, in some example embodiments, when the second test pattern includes the TEG 120b, the second measurement device 12 may include an SEM and/or an X-ray spectrometer. The test error data generated as described above may be fed back to the photolithography process equipment 13.

According to some example embodiments, it is possible to provide the semiconductor process system 1 that includes the first and second measurement devices 11 and 12 capable of performing measurement in different ways. In addition, the first measurement device 11 uses the photoresist pattern, and thus, fast feedback is possible. Also, the second measurement device 12 uses the second overlay pattern 120a and/or the TEG 120b similar to an actual circuit pattern, and thus, a misalignment value similar to that of the actual circuit pattern may be extracted. Therefore, test consistency may be improved and/or increased. In the semiconductor device formed using the semiconductor process system 1 according to some example embodiments, defects due to misalignment may be reduced or prevented. Also, the semiconductor process system 1 may improve and/or increase productivity.

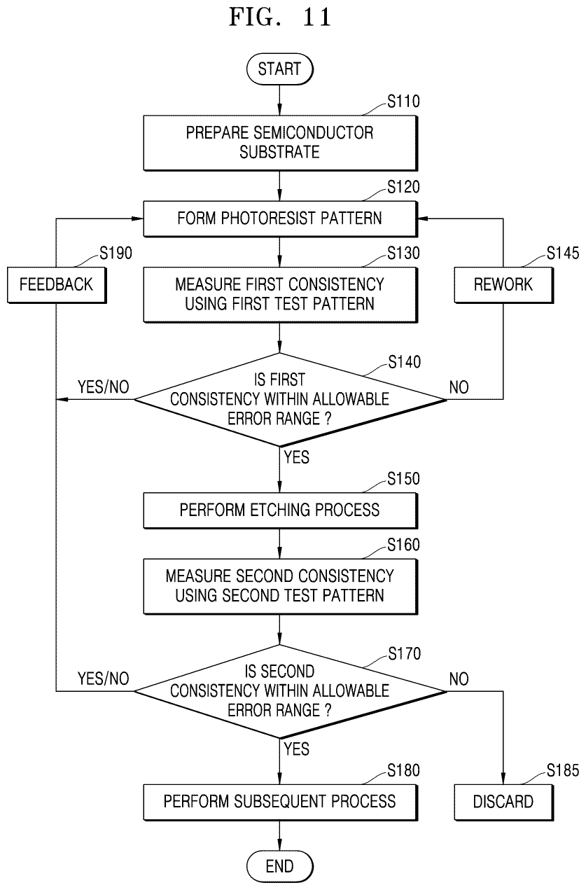

FIG. 11 is a flowchart showing a method of testing a semiconductor device using test groups, according to an example embodiment. A description is given below with reference to FIGS. 1 to 10 together.

Referring to FIG. 11, a semiconductor substrate 10 may be prepared into a substrate processing space (S110). The substrate processing space may include, for example, a processing chamber of a cluster tool.

Subsequently, a photoresist pattern may be formed on the semiconductor substrate 10 (S120). The photoresist pattern may include the first overlay patterns 110a, 110b, 110c, 110d, and 110e of FIGS. 3 to 8.

As described above, the first overlay patterns 110a, 110b, 110c, 110d, and 110e may include a plurality of grating-shaped patterns, a plurality of bar-shaped patterns, and/or a plurality of slit-shaped patterns, but example embodiments are not limited thereto. For example, the first overlay patterns 110a, 110b, 110c, 110d, and 110e may include line-and-space patterns. Each of the first overlay patterns 110a, 110b, 110c, 110d, and 110e may have a pinwheel shape, and line-and-space patterns of each of the first overlay patterns 110a, 110b, 110c, 110d, and 110e in each of the four quadrants may be arranged perpendicularly and parallel to each other.

The first overlay patterns 110a and 110b of FIGS. 3 and 5 may include a Moiré pattern. In the Moiré pattern, the pitch of an upper pattern and the pitch of a lower pattern may be different from each other.

Also, the first overlay patterns 110a and 110c of FIGS. 3 and 6 may include an IBO mark. The IBO mark may include the main patterns MP-1 and MP-2 formed in the lower layers and the vernier patterns VP-1 and VP-2 formed in the current layers.

The first overlay patterns 110b, 110d, and 110e of FIGS. 5, 7, and 8 may include a DBO mark. For example, the DBO mark may include the lower pattern DBOl and the upper pattern DBOu. For example, in FIGS. 5, 7, and 8, the lower pattern DBOl may be formed on the lower layer of the semiconductor substrate 10 and the upper pattern DBOu may be formed on the upper layer of the semiconductor substrate 10.

Next, first consistency is measured using the first overlay patterns 110a, 110b, 110c, 110d, and 110e (S130). For example, the first consistency may include first overlay consistency. The first overlay consistency is measured using, for example, the first measurement device 11 of FIG. 9.

The first overlay patterns 110a and 110c of FIGS. 3 and 6 include the IBO mark, and thus, the first measurement device 11 may measure the overlay by performing signal processing on an optic/camera image of the IBO mark. For example, the first measurement device 11 may perform the signal processing on the images of the main patterns MP-1 and MP-2 and the vernier patterns VP-1 and VP-2 to calculate relative positions between the main patterns MP-1 and MP-2 and the vernier patterns VP-1 and VP-2, thereby measuring the overlay.

The first overlay patterns 110b, 110d, and 110e of FIGS. 5, 7, and 8 include the DBO mark, and thus, the first measurement device 11 may detect light incident on and diffracted from the DBO mark and may perform signal processing on the diffracted light to measure the overlay. For example, the first measurement device 11 may detect signals reflected and diffracted from the DBO mark, compare the intensities of primary components of the diffracted signals, and measure the overlay.

Then, it is determined whether or not the measured first consistency is within an allowable error range (S140). If the first consistency is out of the allowable error range, the photoresist pattern formed in operation S120 may be removed and a new photoresist pattern may be formed through rework (S145). To this end, the measured first consistency data may be fed back (S190).

Otherwise, if the first consistency is within the allowable error range, etching using the photoresist pattern as an etching mask may be performed in a subsequent process (S150). In addition, even if the first consistency is not out of the allowable error range, the measured first consistency data may be fed back in order to perform more precise processing on a next die, substrate, or lot (S190).

In some example embodiments, a process of forming a conductor wire may be additionally performed on the etched pattern. The process of forming the conductor wire may be performed by, for example, a damascene process, but example embodiments are not limited thereto.

Subsequently, a second test pattern may be formed on the semiconductor substrate 10. The second test pattern may include the second overlay pattern 120a and/or the TEG 120b FIGS. 3 to 8. The second test pattern may include a conductive material. In another example embodiment, the second test pattern may not include a conductive material. Each of second test patterns may have a planar area smaller than that of each of the first overlay patterns 110a, 110b, 110c, 110d, and 110e. Also, the mark of each of the second test patterns may have a length, width, and pitch smaller than those of each of the overlay marks of the first overlay patterns 110a, 110b, 110c, 110d, and 110e.

For example, the second overlay pattern 120a may include an overlay pattern measured during an ACI. The ACI may actually refer to an inspection after an etching process for forming a pattern on a substrate.

For example, the second overlay pattern 120a may include a conductive material. The second overlay pattern 120a may include the first additional overlay mark 120X extending in the first horizontal direction (X direction) and the second and third additional overlay marks 120Y-1 and 120Y-2 extending in the second horizontal direction (Y direction). In a plan view, each of the first to third additional overlay marks 120X, 120Y-1, and 120Y-2 may have a grating, a bar, and/or a slit shape. The second and third additional overlay marks 120Y-1 and 120Y-2 may be spaced apart from each other in the first horizontal direction (X direction). The shape of the second overlay pattern 120a is not limited thereto and may be variously modified.

Each of the first to third additional overlay marks 120X, 120Y-1, and 120Y-2 may have a corresponding cell pattern in the chip region CA. In some example embodiments, each of the first to third additional overlay marks 120X, 120Y-1, and 120Y-2 may be formed simultaneously with a specific cell pattern located in the chip region CA at the same vertical level as each of the first to third additional overlay marks 120X, 120Y-1, and 120Y-2. In another example embodiment, each of the first to third additional overlay marks 120X, 120Y-1, and 120Y-2 may be formed at a different time point from a specific cell pattern located in the chip region CA at the same vertical level as each of the first to third additional overlay marks 120X, 120Y-1, and 120Y-2.

The TEG 120b may include a pattern for measuring a CD of a pattern of the semiconductor substrate 10. For example, the TEG 120b may include a pattern for measuring the thickness and/or line width of the pattern of the semiconductor substrate 10.

The TEG 120b may include a plurality of patterns for testing a manufacturing process of a semiconductor device and characteristics of the completed semiconductor device. FIGS. 6 to 8 illustrate, as an example, that the TEG 120b includes a rectangular mark and another rectangular mark surrounding the rectangular mark, but the shape and arrangement of the marks of the TEG 120b may be variously modified.

The test pattern groups 100, which include the first test patterns 110a, 110b, 110c, 110d, and 110e and the second test patterns 120a and 120b, may include a central region CR and an edge region ER surrounding the central region CR. The horizontal area of the central region CR may be less than the horizontal area of the edge region ER. Each of the marks of the first test patterns 110a, 110b, 110c, 110d, and 110e may have a horizontal area larger than that of each of the marks of the second test patterns 120a and 120b.

The first test patterns 110a, 110b, 110c, 110d, and 110e may be disposed on the edge region ER and the second test patterns 120a and 120b may be disposed on the central region CR. The edge region ER may be divided into four quadrants having a quadrangular shape (e.g., a rectangular or a square shape). The first test patterns 110a, 110b, 110c, 110d, and 110e may be located in each of the quadrants.

Subsequently, second consistency is measured using the second test patterns 120a and 120b (S160).

The second consistency may be measured using, for example, the second measurement device 12 of FIG. 9. For example, when measuring the second overlay pattern 120a, the second measurement device 12 may include an SEM. Also, when measuring the TEG 120b, the second measurement device 12 may include an SEM and/or an X-ray spectrometer.

Then, it is determined whether or not the measured second consistency is within an allowable error range (S170). If the second consistency is out of the allowable error range, the substrate may be discarded (S185). However, in some example embodiments, even if the second consistency is out of the allowable error range, it is not necessary to discard the substrate. In some cases, rework may be performed on the substrate, and subsequent processes may be continued after feedback of relevant data. However, in some example embodiments, the measured second test consistency data may be fed back in order to perform more precise processing on a next substrate or lot (S190).

Otherwise, if the second consistency is within the allowable error range, a scheduled subsequent process may continue (S180). In addition, even if the second consistency is not out of the allowable error range, the measured second consistency data may be fed back in order to perform more precise processing on a next die, substrate, or lot (S190).

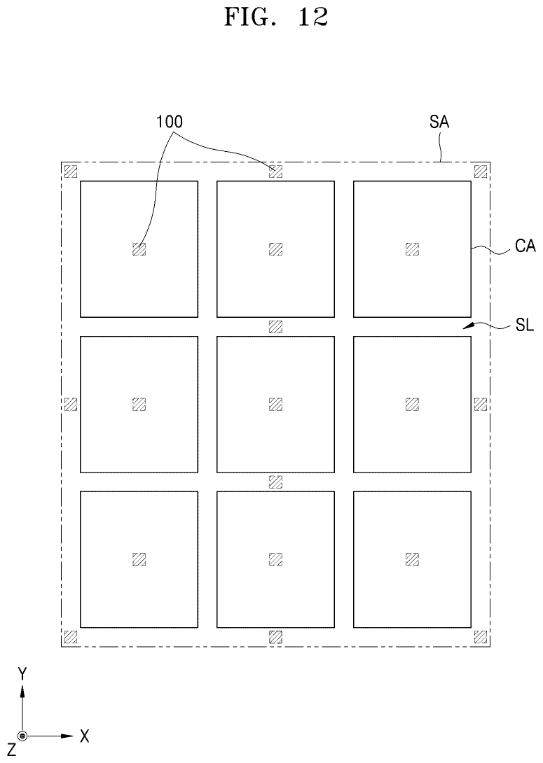

FIG. 12 is a partially enlarged view of some semiconductor dies of FIG. 1. A description is given below with reference to FIGS. 1 to 11 together.

Referring to FIG. 12, a plurality of test pattern groups 100 may be arranged on a semiconductor substrate 10 and may be evenly arranged within one shot region SA.

In some example embodiments, a plurality of chip regions CA may be arranged in one shot region SA. The test pattern groups 100 may be arranged at the same positions within each of the plurality of chip regions CA. For example, the positions of the test pattern groups 100 arranged in one of the plurality of chip regions CA may be the same as the positions of the test pattern groups 100 arranged in another one of the plurality of chip regions CA.

The test pattern groups 100a, 100b, 100c, and 100d illustrated in FIGS. 5 to 8 may be arranged on the semiconductor substrate 10.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been shown and described with reference to example embodiments thereof, it will be understood that various changes in form and details may be made therein without departing from the spirit and scope of the following claims.

What is claimed is:

1. A semiconductor device comprising:
a semiconductor substrate;
a first test pattern on the semiconductor substrate; and
a second test pattern adjacent to the first test pattern, wherein
the first test pattern includes an overlay pattern, and
the second test pattern includes a test element group.

2. The semiconductor device of claim 1, wherein the first test pattern surrounds the second test pattern in a plan view.

3. The semiconductor device of claim 1, wherein the first test pattern comprises a first line-and-space pattern extending in a first horizontal direction and a second line-and-space pattern extending in a second horizontal direction.

4. The semiconductor device of claim 1, wherein
the first test pattern comprises a plurality of lower marks and a plurality of upper marks that are at different vertical levels, and
the plurality of lower marks and the plurality of upper marks respectively overlap each other in a vertical direction.

5. The semiconductor device of claim 1, wherein
the first test pattern comprises a plurality of lower marks and a plurality of upper marks that are at different vertical levels, and
the plurality of lower marks and the plurality of upper marks are respectively spaced apart from each other in a horizontal direction.

6. The semiconductor device of claim 5, wherein
the first test pattern is arranged in a plurality of quadrants, and
in each of the plurality of quadrants,
the plurality of lower marks and the plurality of upper marks are respectively spaced apart from each other in a horizontal direction parallel to a direction in which each of the plurality of lower marks and each of the plurality of upper marks extend.

7. The semiconductor device of claim 5, wherein
the first test pattern is arranged in a plurality of quadrants, and
in each of the plurality of quadrants,
the plurality of lower marks and the plurality of upper marks are respectively spaced apart from each other in a horizontal direction perpendicular to a direction in which each of the plurality of lower marks and each of the plurality of upper marks extend.

8. The semiconductor device of claim 1, wherein the first test pattern comprises at least one of an image based overlay (IBO) pattern and a diffraction based overlay (DBO) pattern.

9. A semiconductor device comprising:
a semiconductor substrate including an in-cell region and a scribe lane defining the in-cell region;
a first test pattern on the semiconductor substrate; and
a second test pattern adjacent to the first test pattern, wherein
the first test pattern includes a first overlay pattern,
the first test pattern includes a plurality of lower marks and a plurality of upper marks that are at different vertical levels,
at least one of the plurality of lower marks and at least one of the plurality of upper marks overlap each other in a vertical direction, and
a pitch of each of the plurality of lower marks is different from a pitch of each of the plurality of upper marks.

10. The semiconductor device of claim 9, wherein the second test pattern comprises a first sub-pattern and a second sub-pattern respectively corresponding to a first cell pattern and a second cell pattern that are at different vertical levels in the in-cell region.

11. The semiconductor device of claim 9, wherein the second test pattern comprises a plurality of marks for measuring a critical dimension (CD).

12. The semiconductor device of claim 9, wherein the pitch of each of the plurality of lower marks and the plurality of upper marks is in a range from about 300 nanometers to about 900 nanometers.

13. The semiconductor device of claim 9, wherein a length of each of the plurality of lower marks and a length of each of the plurality of upper marks are greater than a length of a mark of the second test pattern.

14. The semiconductor device of claim 9, wherein the plurality of lower marks and the plurality of upper marks are arranged in a Moiré pattern.

15. The semiconductor device of claim 9, wherein
the first test pattern and the second test pattern correspond to one test pattern group, and
the test pattern group is on the scribe lane.

16. A semiconductor device comprising:
a semiconductor substrate including an in-cell region and a scribe lane defining the in-cell region;
a first overlay pattern on the semiconductor substrate; and
a second overlay pattern surrounded by the first overlay pattern, wherein
the first overlay pattern includes a plurality of lower marks and a plurality of upper marks that are at different vertical levels,
at least one of the plurality of lower marks and at least one of the plurality of upper marks overlap each other in a vertical direction,
a pitch of each of the plurality of lower marks is different from a pitch of each of the plurality of upper marks,
the first overlay pattern comprises an after development inspection (ADI) overlay pattern, and
the second overlay pattern comprises an after cleaning inspection (ACI) overlay pattern.

17. The semiconductor device of claim 16, wherein
the first overlay pattern comprises a first line-and-space pattern extending in a first horizontal direction and a second line-and-space pattern extending in a second horizontal direction, and
the second overlay pattern includes a third line-and-space pattern extending in the first horizontal direction and a fourth line-and-space pattern extending in the second horizontal direction.

18. The semiconductor device of claim 17, wherein
a length of each of the first and second line-and-space patterns is in a range from about 5 micrometers to about 35 micrometers, and
a length of each of the third and fourth line-and-space patterns is in a range from about 3 micrometers to about 20 micrometers.

19. The semiconductor device of claim 16, wherein
the first overlay pattern and the second overlay pattern correspond to one overlay pattern group, and
the overlay pattern group is on the in-cell region or the scribe lane.

20. The semiconductor device of claim 16, wherein a horizontal area of the first overlay pattern is greater than a horizontal area of the second overlay pattern.
